(19) United States
(12) Patent Application Publication
(10) Pub. No.: US 2021/0066109 A1
(43) Pub. Date: Mar. 4, 2021

(54) METHOD OF MANUFACTURING SEMICONDUCTOR DEVICE

(71) Applicants: KABUSHIKI KAISHA TOSHIBA, Minato-ku (JP); TOSHIBA ELECTRONIC DEVICES & STORAGE CORPORATION, Minato-ku (JP)

(72) Inventor: Seiya SAKAKURA, Hakusan (JP)

(73) Assignees: KABUSHIKI KAISHA TOSHIBA, Minato-ku (JP); TOSHIBA ELECTRONIC DEVICES & STORAGE CORPORATION, Minato-ku (JP)

(21) Appl. No.: 16/807,648

(22) Filed: Mar. 3, 2020

(30) Foreign Application Priority Data
Sep. 3, 2019 (JP) 2019-160595

(51) Int. Cl. H01L 21/683; H01L 21/02; H01L 21/78

(52) U.S. Cl. CPC H01L 21/6836; H01L 2221/68327; H01L 21/78; H01L 21/02035

(57) ABSTRACT

A method of manufacturing a semiconductor device includes thinning a wafer at a back-surface side so that the wafer has an inner portion inside a peripheral portion, the peripheral portion surrounding the inner portion along an outer edge of the wafer, the inner portion having a thickness thinner than a thickness of the peripheral portion; attaching a first support member to the wafer at the back-surface side; cutting the wafer at a front surface side of the wafer along a boundary between the inner portion and the peripheral portion so that the inner portion is separated from the peripheral portion and a back-surface of the inner portion coheres on the first support member; and processing a front surface side of the inner portion while holding the inner portion and the peripheral portion on the first support member.

### CROSS-REFERENCE TO RELATED APPLICATIONS

This application is based upon and claims the benefit of priority from Japanese Patent Application No. 2019-160595, filed on Sep. 3, 2019; the entire contents of which are incorporated herein by reference.

### FIELD

Embodiments relate to a method of manufacturing a semiconductor device.

### BACKGROUND

In the manufacturing process of semiconductor devices, a semiconductor wafer is processed thin to achieve a semiconductor chip with a desired thickness. In the processes performed after the wafer is thinned, however, the means for reinforcing the mechanical strength of the wafer are necessary, which increase the manufacturing cost.

### BRIEF DESCRIPTION OF THE DRAWINGS

FIGS. 1A and 1B are schematic views showing a semiconductor wafer according to an embodiment;

FIG. 2A to FIG. 4C are schematic cross-sectional views showing a manufacturing process of a semiconductor element according to the embodiment;

FIGS. 5A to 5C are schematic cross-sectional views showing a manufacturing process of a semiconductor element according to a modification of the embodiment; and

FIG. 6 is a schematic cross-sectional view showing a semiconductor device according to the embodiment.

### DETAILED DESCRIPTION

According to one embodiment, a method of manufacturing a semiconductor device includes thinning a wafer at a back-surface side so that the wafer has an inner portion inside a peripheral portion, the peripheral portion surrounding the inner portion along an outer edge of the wafer, the inner portion having a thickness thinner than a thickness of the peripheral portion; attaching a first support member to the wafer at the back-surface side; cutting the wafer at a front surface side of the wafer along a boundary between the inner portion and the peripheral portion so that the inner portion is separated from the peripheral portion and a back-surface of the inner portion coheres on the first support member; and processing a front surface side of the inner portion while holding the inner portion and the peripheral portion on the first support member.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

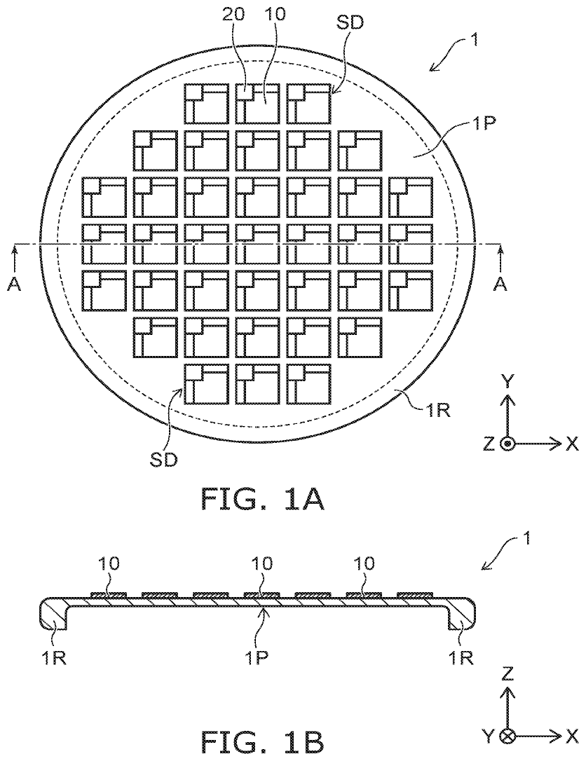

FIGS. 1A and 1B are schematic views showing a semiconductor wafer 1 according to an embodiment. FIG. 1A is a plan view showing a front surface of the semiconductor wafer 1. FIG. 1B is a schematic view showing a cross-section along A-A line shown in FIG. 1A. The semiconductor wafer 1 is, for example, a silicon wafer.

As shown in FIG. 1A, a plurality of semiconductor elements SD is provided in the semiconductor wafer. Each semiconductor element SD is, for example, a MOSFET. The semiconductor element SD includes a source electrode and a gate pad 20 provided on the front surface of the semiconductor wafer 1.

The semiconductor wafer 1 includes a peripheral portion 1R provided along the periphery thereof, and a thin portion 1P. The thin portion 1P is positioned inside the peripheral portion 1R. The semiconductor element SD is provided in the thin portion 1P.

As shown in FIG. 1B, the semiconductor wafer 1 has the recessed portion at the back-surface side in which the semiconductor wafer 1 is selectively removed inside the peripheral portion 1R. The thin portion 1P is formed by, for example, selectively grinding the semiconductor wafer 1 at the back-surface side. The peripheral portion 1R has the thickness of, for example, 600 to 800 micrometers (μm) in the Z-direction. The thin portion 1P has the thickness of, for example, 40 to 100 μm in the Z-direction.

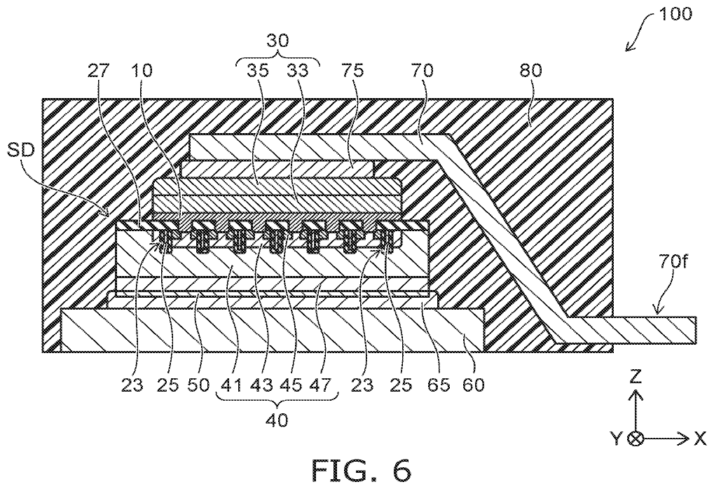

The semiconductor wafer 1 is, for example, an n-type silicon wafer. After the thin portion 1P is formed, for example, the n-type drain layer and the drain electrode not shown are provided at the back-surface side of the semiconductor wafer 1 (see FIG. 6). That is, after the thin portion 1P is formed, a n-type impurity is ion-implanted at the back-surface side of the semiconductor wafer 1, and then, a metal film is formed which serves as the drain electrode. Through these manufacturing steps, the mechanical strength of the semiconductor wafer 1 is maintained by the peripheral portion 1R.

It should be noted that the semiconductor element SD according to the embodiment is not limited to the MOSFET. For example, the semiconductor element SD may be an IGBT (Insulated Gate Bipolar Transistor) or a diode. After forming the thin portion 1P is formed, the manufacturing steps performed at the back-surface side of the semiconductor wafer 1 are different in the semiconductor elements.

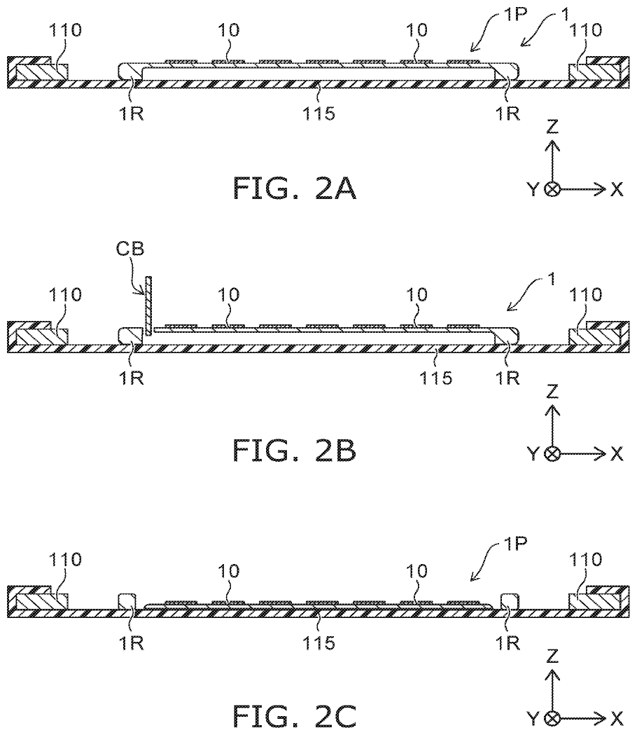

Hereinafter, with reference to FIGS. 2A to 4C, a method for manufacturing the semiconductor element SD according to the embodiment will be described. FIGS. 2A to 4C are schematic cross-sectional views showing the manufacturing process of the semiconductor element SD according to the embodiment.

As shown in FIG. 2A, for example, a first support member (hereinafter, a resin film 115) is attached to the back-surface of the semiconductor wafer 1. The resin film 115 is flexible and has an adhesive layer on the front surface thereof. For example, it is preferable to use the support member such as a UV tape which loses the adhesive force by the irradiation of ultraviolet light.

The resin film 115 is held with tension applied by, for example, a metal ring 110. The semiconductor wafer 1 is held on the resin film 115. The semiconductor wafer 1 is adhered to the resin film 115 at the peripheral portion 1R thereof. The center of the thin portion 1P may also be adhered to the resin film 115. Although not shown in FIG. 2A, the resin film 115 may be attached to the semiconductor wafer 1 such that the center of the thin portion 1P is in contact with the resin film 115 owing to the flexibility thereof and the bending of the thin portion 1P.

As shown in FIG. 2B, the semiconductor wafer 1 is cut along the boundary between the peripheral portion 1R and the thin portion 1P. The semiconductor wafer 1 is cut by, for example, a precision cutting blade CB or a laser cutter. Thereby, the thin portion 1P is separated from the peripheral portion 1R.

As shown in FIG. 2C, the thin portion 1P is held such that the entire back-surface thereof is in contact with the resin film 115. Thereby, the resin film 115 coheres on the back-surface of the thin portion 1P. The peripheral portion 1R is also held on the resin film 115.

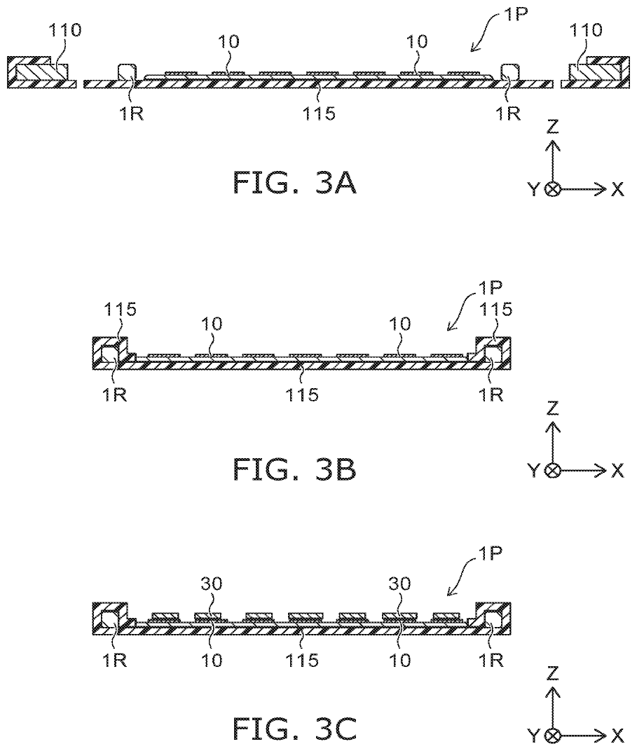

As shown in FIG. 3A, the resin film 115 is cut at the space between the peripheral portion 1R and the metal ring 110. The resin film 115 is held with tension applied by the peripheral portion 1R, and the thin portion 1P is held on the resin film 115.

As shown in FIG. 3B, the periphery of the resin film 115 outside the peripheral portion 1R is folded back to cover the peripheral portion 1R and the outer edge of the thin portion 1P. The resin film 115 protects the back-surface and the outer edge of the thin portion 1P, while exposing the front-surface thereof. The resin film 115 also protects the peripheral portion 1R.

As shown in FIG. 3C, the metal layers 30 are formed on the source electrodes 10, respectively, on the front surface of the thin portion 1P. The metal layers 30 are formed using, for example, an electroless plating method. The metal layers 30 each have, for example, a multilayer structure including a nickel (Ni) layer and a gold (Au) layer.

For example, the nickel layer is formed on the source electrode 10, and then, the gold layer is formed on the nickel layer. While these steps, the resin film 115 protects the peripheral portion 1R, the back surface and the outer edge of the thin portion 1P from the plating solution, and prevents other metal layer unintentionally formed thereon.

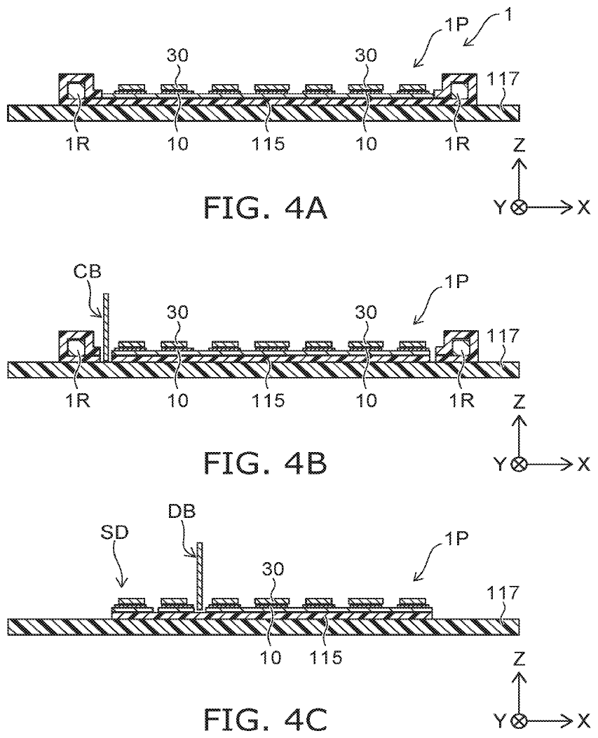

As shown in FIG. 4A, a second support member, for example, a dicing film 117 is attached to the resin film 115 at the back-surface side of the semiconductor wafer 1. The dicing film 117 is held with tensioned applied by, for example, a metal ring (not shown).

As shown in FIG. 4B, the resin film 115 is cut along the boundary between the peripheral portion 1R and the thin portion 1P. The resin film 115 is cut using, for example, a precision cutting blade CB or a laser cutter.

As shown in FIG. 4C, the peripheral portion 1R is removed from the dicing film 117, and the thin portion 1P remains on the dicing film 117. Then, the thin portion 1P is cut using, for example, a dicing blade DB and divided into the semiconductor element SD chips.

Further, to reduce the adhesive strength in the adhesive layer of the resin film 115, for example, ultraviolet light irradiation is performed at the back-surface side thereof through the dicing film 117. Then, the semiconductor element SD is picked up from the resin film 115 and mounted on, for example, a lead frame.

In the manufacturing process described above, the metal layer 30 is formed while the resin film 115 coheres at the back-surface side of the semiconductor wafer 1. Thereby, it is possible to prevent the plating solution from penetrating and unintentionally forming a metal layer at the back-surface side of the semiconductor wafer 1.

For example, when the thin portion 1P is not separated from the peripheral portion 1R (see FIG. 1B), it is difficult to attach the protective film to coheres on the recessed portion at the back-surface side of the semiconductor wafer 1. Moreover, such a work makes the manufacturing efficiency lower, resulting in the increase of manufacturing cost.

According to the manufacturing method according to the embodiment, it is possible to more easily protect the back-surface side and the peripheral portion 1R of the semiconductor wafer 1, and the manufacturing cost of the semiconductor element SD is reduced.

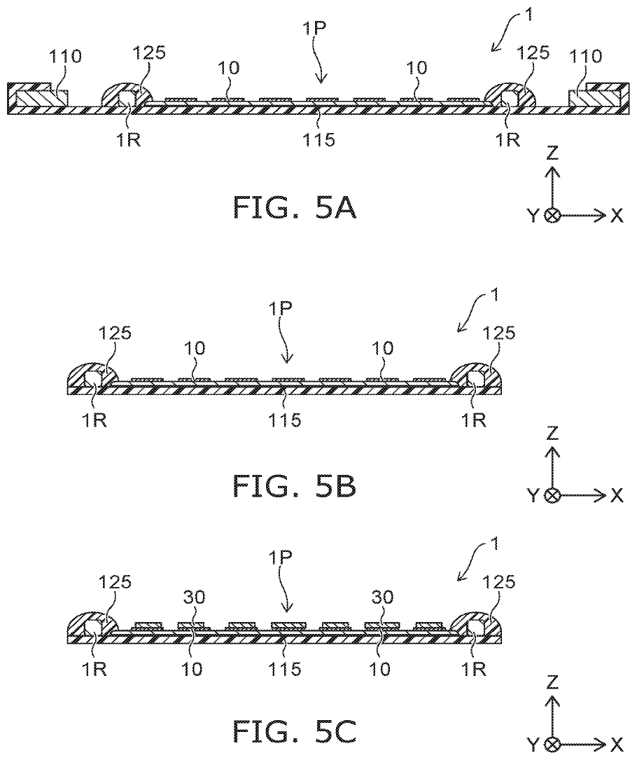

FIGS. 5A to 5C are schematic cross-sectional views showing a manufacturing process of the semiconductor element SD according to a modification of the embodiment. FIGS. 5A to 5C show the manufacturing steps following to the manufacturing step shown in FIG. 2C.

As shown in FIG. 5A, the thin portion 1P are separated from the peripheral portion 1R, and the back-surface of the thin portion 1P coheres on the resin film 115. Then, the resist 125 is applied to cover the outer edge of the thin portion 1P and the peripheral portion 1R.

As shown in FIG. 5B, the semiconductor wafer 1 is separated from the metal ring 110 by cutting the resin film 115. Also, in this case, the semiconductor wafer 1 is supported by the resin film 115 with tension applied by the peripheral portion 1R.

As shown in FIG. 5C, the metal layers 30 are formed on the source electrodes 10, respectively. The metal layers 30 are formed using, for example, the electroless plating method. Also, in this example, the back-surface of the thin portion 1P coheres on the resin film 115, and the peripheral portion 1R and the outer edge of the thin portion 1P are protected by a resist 125. Thereby, the semiconductor wafer 1 is prevented from contacting the plating solution except for the front-surface of the thin portion 1P.

Subsequently, the dicing film 117 is attached to the resin film 115 at the back-surface side thereof (see FIG. 4A). Then, the resin film 115 is cut along the boundary between the thin portion 1P and the resist 125 (see FIG. 4A). Further, the peripheral portion 1R and the resist 125 are removed from the dicing film 117, and the thin portion 1P is divided into the semiconductor element SD chips (see FIG. 4C).

Also, in this example, it is possible to more easily protect the back-surface of the semiconductor wafer 1 and the peripheral portion 1R by the resin film 115, and the manufacturing cost of the semiconductor element SD is reduced. The protection member that covers the outer edge of the thin portion 1P and the peripheral portion 1R is not limited to the resist 125. Such as a resin tape may be attached thereto in place of the resist 125.

FIG. 6 is a schematic cross-sectional view illustrating a semiconductor device 100 according to the embodiment. The semiconductor device 100 includes the semiconductor element SD mounted on a base plate 60.

As shown in FIG. 6, the semiconductor element SD includes a semiconductor part 40. The semiconductor part 40 is formed by dividing the thin portion 1P of the semiconductor wafer 1. The semiconductor part 40 is provided between the source electrode 10 and a drain electrode 50. The semiconductor part 40 includes, for example, an n-type drift layer 41, a p-type diffusion layer 43, an n-type source layer 45, and an n-type drain layer 47.

For example, the n-type drift layer 41 extends in the X-direction and the Y-direction along the drain electrode 50. The p-type diffusion layer 43 is provided between the source electrode 10 and the n-type drift layer 41. The n-type source layer 45 is selectively provided between the source electrode 10 and the p-type diffusion layer 43 and electrically connected to the source electrode 10. The n-type drain layer 47 is provided between the n-type drift layer 41 and the drain electrode 50 and electrically connected to the drain electrode 50.

The semiconductor element SD further includes a gate electrode 25 provided between the source electrode 10 and the semiconductor part 40. The gate electrode 25 is provided in the trench gate structure and electrically connected to the gate pad 20 (see FIG. 1A). The gate electrode 25 extends in the semiconductor part 40 and is electrically isolated from the semiconductor part 40 by a gate insulating film 23. The gate electrode 25 is electrically isolated from the source electrode 10 by an interlayer insulating film 27.

The semiconductor element SD is mounted on the base plate 60 via a bonding member 65, for example, a solder. Further, the source electrode 10 of the semiconductor element SD is electrically connected to a connector 70 via the metal layer 30 and a bonding member 75. The semiconductor element SD and the connector 70 are sealed with, for example, a resin member 80. One end 70f of the connector 70 is, for example, a source terminal extending outside the resin member 80.

The semiconductor element SD is connected to the connector 70 via the bonding member 75, for example, a solder. The metal layer 30 is formed on the source electrode 10 to prevent the bonding member 75 from migrating into the semiconductor part 40. The metal layer 30 has, for example, a stacked structure which includes a nickel layer 33 and a gold layer 35. The metal layer 30 has a layer thickness of several dozen μm.

In the manufacturing process of the semiconductor element SD, the n-type drain layer 47, for example, is formed after the semiconductor wafer 1 is thinned. In this manufacturing step, the heat treatment is performed to form the n-type drain layer 47 by activating the n-type impurity. If the metal layer 30 is formed before the semiconductor wafer 1 is thinned, the metal element in the metal layer 30 is diffused into the semiconductor part 40 by the heat treatment, and the semiconductor element SD may have the deteriorated characteristics. Therefore, it is preferable to form the metal layer 30 in the last step before the semiconductor 1 is diced.

In the manufacturing method according to the embodiment, while forming the metal layer 30, the semiconductor wafer 1 having a thin thickness is easily protected at the back-surface side thereof by the resin film 115, and the manufacturing cost is reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A Method of manufacturing a semiconductor device, the method comprising:
thinning a wafer at a back-surface side so that the wafer has an inner portion inside a peripheral portion, the peripheral portion surrounding the inner portion along an outer edge of the wafer, the inner portion having a thickness thinner than a thickness of the peripheral portion;
attaching a first support member to the wafer at the back-surface side;
cutting the wafer at a front surface side of the wafer along a boundary between the inner portion and the peripheral portion so that the inner portion is separated from the peripheral portion and a back-surface of the inner portion coheres on the first support member; and
processing a front surface side of the inner portion while holding the inner portion and the peripheral portion on the first support member.

2. The method according to claim 1, wherein the first support member is a resin film.

3. The method according to claim 2, further comprising:
cutting the first support member along an outer edge of the wafer; and
folding back the first support member to cover the peripheral portion and an outer edge of the inner portion before processing the front surface side of the inner portion.

4. The method according to claim 3, wherein a metal film is formed on the front surface of the inner portion while processing the front surface side of the inner portion.

5. The method according to claim 3, wherein a metal film is formed using a plating method on a front surface of the inner portion while processing the front surface side of the inner portion.

6. The method according to claim 1, further comprising:
forming a protection member covering the peripheral portion and an outer edge of the inner portion before processing the front surface side of the inner portion.

7. The method according to claim 6, further comprising:
cutting the first support member along a periphery of the protection member,
the processing the front surface side of the inner portion being performed after cutting the first support member.

8. The method according to claim 7, wherein a metal film is formed on the front surface of the inner portion while processing the front surface side of the inner portion.

9. The method according to claim 8, further comprising:
attaching a second support member to the first support member, the first support member being provided between the wafer and the second support member,
removing the peripheral portion and the outer edge of the inner portion held on the second support member via the first support member, and
cutting the inner portion into chips.

10. The method according to claim 7, wherein a metal film is formed using a plating method on a front surface of the inner portion while processing the front surface side of the inner portion.

11. The method according to claim 10, further comprising:
attaching a second support member to the first support member, the first support member being provided between the wafer and the second support member,
removing the peripheral portion and the outer edge of the inner portion held on the second support member via the first support member, and
cutting the inner portion into chips.

12. The method according to claim 10, further comprising:
cutting the first support member along an outer edge of the inner portion at a space between the inner portion and the peripheral portion,
the peripheral portion being removed with a cut-off portion of the first support member.

13. The method according to claim 1, wherein the wafer is thinned by selectively grinding the back-surface side.

14. The method according to claim 4, further comprising:
attaching a second support member to the first support member, the first support member being provided between the wafer and the second support member,
removing the peripheral portion and the outer edge of the inner portion held on the second support member via the first support member, and
cutting the inner portion into chips.

15. The method according to claim 5, further comprising:
attaching a second support member to the first support member, the first support member being provided between the wafer and the second support member,
removing the peripheral portion and the outer edge of the inner portion held on the second support member via the first support member, and
cutting the inner portion into chips.

16. The method according to claim 5, further comprising:
cutting the first support member along an outer edge of the inner portion at a space between the inner portion and the peripheral portion,
the peripheral portion being removed with a cut-off portion of the first support member.
